(19) United States
(12) Patent Application Publication
(10) Pub. No.: US 2025/0266319 A1
(43) Pub. Date: Aug. 21, 2025

(54) REDUCING THE SPREADING OF MATERIAL(S) MIGRATING FROM THERMAL MANAGEMENT AND/OR ELECTROMAGNETIC INTERFERENCE (EMI) MITIGATION MATERIALS

(71) Applicant: Laird Technologies, Inc., Chesterfield, MO (US)

(72) Inventors: Shourya JAIN, Philadelphia, PA (US); Jason L. STRADER, Pepper Pike, OH (US); Jonathan Andrew WELDON, Dallas, TX (US); Jeffrey Scott METH, Landenberg, PA (US); Yuqin LI, Cleveland, OH (US)

(21) Appl. No.: 19/055,584

(22) Filed: Feb. 18, 2025

Related U.S. Application Data
(60) Provisional application No. 63/557,123, filed on Feb. 23, 2024.
(60) Provisional application No. 63/556,858, filed on Feb. 22, 2024.
(60) Provisional application No. 63/555,337, filed on Feb. 19, 2024.

(51) Int. Cl. H01L 23/42; H01L 23/552; H05K 9/00

(52) U.S. Cl. CPC H01L 23/42; H01L 23/552; H05K 9/0081

(57) ABSTRACT

The present disclosure relates to reducing the spreading of material(s) migrating (e.g., reducing oil bleed spreading, etc.) from thermal management and/or electromagnetic interference (EMI) mitigation materials (e.g., thermal interface materials (TIMs), EMI absorbers, thermally-conductive EMI absorbers, electrically-conductive elastomers (ECEs), electrically-conductive composites, combinations thereof, etc.) and other polymer-inorganic composite materials used for other purposes. The spreading of material(s) migrating from a composite may be reduced without having to change a formulation of the composite. An exemplary method includes configuring or providing a component (e.g., an electronic device component, etc.) with a surface having a surface roughness characterized by at least one or both of: an arithmetical mean height (Sa) no greater than about 1.25 micrometers and a root mean square height (Sq) no greater than about 1.5 micrometers. The surface having the surface roughness is usable for reducing the spreading of material(s), if any, migrating from a composite along the surface.

### CROSS-REFERENCE TO RELATED APPLICATIONS

This application claims the benefit and priority of U.S. Provisional Patent Application No. 63/555,337 filed Feb. 19, 2024, U.S. Provisional Patent Application No. 63/556,858 filed Feb. 22, 2024, and U.S. Provisional Patent Application No. 63/557,123 filed Feb. 23, 2024. The entire disclosures of these provisional patent applications are incorporated herein by reference.

### FIELD

The present disclosure relates to reducing the spreading of material(s) migrating (e.g., reducing oil bleed spreading, etc.) from thermal management and/or electromagnetic interference (EMI) mitigation materials (e.g., thermal interface materials (TIMs), EMI absorbers, thermally-conductive EMI absorbers, electrically-conductive elastomers (ECEs), electrically-conductive composites, combinations thereof, etc.) and other polymer-inorganic composite materials used for other purposes.

### BACKGROUND

This section provides background information related to the present disclosure which is not necessarily prior art.

Electrical components, such as semiconductors, integrated circuit packages, transistors, etc., typically have pre-designed temperatures at which the electrical components optimally operate. Ideally, the pre-designed temperatures approximate the temperature of the surrounding air. But the operation of electrical components generates heat. If the heat is not removed, the electrical components may then operate at temperatures significantly higher than their normal or desirable operating temperature. Such excessive temperatures may adversely affect the operating characteristics of the electrical components and the operation of the associated device.

To avoid or at least reduce the adverse operating characteristics from the heat generation, the heat should be removed, for example, by conducting the heat from the operating electrical component to a heat sink. The heat sink may then be cooled by conventional convection and/or radiation techniques. During conduction, the heat may pass from the operating electrical component to the heat sink either by direct surface contact between the electrical component and heat sink and/or by contact of the electrical component and heat sink surfaces through an intermediate medium or thermal interface material (TIM). The thermal interface material may be used to fill the gap between thermal transfer surfaces, in order to increase thermal transfer efficiency as compared to having the gap filled with air, which is a relatively poor thermal conductor.

In addition, a common problem in the operation of electronic devices is the generation of electromagnetic radiation within the electronic circuitry of the equipment. Such radiation may result in electromagnetic interference (EMI) or radio frequency interference (RFI), which can interfere with the operation of other electronic devices within a certain proximity. Without adequate shielding, EMI/RFI interference may cause degradation or complete loss of important signals, thereby rendering the electronic equipment inefficient or inoperable.

A common solution to ameliorate the effects of EMI/RFI is through the use of shields capable of absorbing and/or reflecting and/or redirecting EMI energy. These shields are typically employed to localize EMI/RFI within its source, and to insulate other devices proximal to the EMI/RFI source. These shields may be composed of metal, polymer-inorganic composites, filled foams, foam materials wrapped or coated with absorbing and/or reflecting materials, and the like.

The term “EMI” as used herein should be considered to generally include and refer to EMI emissions and RFI emissions, and the term “electromagnetic” should be considered to generally include and refer to electromagnetic and radio frequency from external sources and internal sources. Accordingly, the term shielding (as used herein) broadly includes and refers to mitigating (or limiting) EMI and/or RFI, such as by absorbing, reflecting, blocking, and/or redirecting the energy or some combination thereof so that it no longer interferes, for example, for government compliance and/or for internal functionality of the electronic component system.

The above mitigation/management materials, if not comprised of metal, often consist of inorganic-polymer composites or metal-polymer composites. The concentration of the inorganic material, which is usually a particle, in the polymer matrices is often high, for the purpose of attaining the desired management of thermal and/or EMI issues.

In some instances, the composites are used in applications where they are compressed between two portions of the device requiring management of thermal and/or EMI issues. This compression may occur during the assembly of a device or during cycles of compression and expansion during use of a device. As a result, the composites must be ‘soft’ so they can readily deflect and absorb the forces of compression, without transferring those forces to the device being protected with the associated risk of physical damage. As is known to those skilled in the art, in some situations the methods used to prepare such soft composites lead to materials from which various organic species may migrate over time, particularly after repeated cycles of compression and expansion. These organic species may consist of polymers, monomers, additives used to form the composite or to enhance its performance during use, complexes of organic materials with inorganic materials, and the like. The term ‘oil bleed’ is commonly used within the industry to describe this phenomenon, and will be used in this document with the understanding that ‘oil’ refers to a range of primarily organic species and ‘bleed’ refers to the movement of materials from within the composites to a location, or locations, external to the composites.

### DRAWINGS

The drawings described herein are for illustrative purposes only of selected embodiments and not all possible implementations, and is not intended to limit the scope of the present disclosure.

FIG. 1 is a line graph of oil bleed spreading percentage versus surface roughness for a low bleed material and a high bleed material. As shown by FIG. 1 and recognized herein, the oil bleed spreading percentage decreases for both the low and high bleed materials as the surface roughness decreases.

FIGS. 2 through 9 include color photographs showing oil bleed spreading thermal interface materials along different surface finishes having different surface roughness. FIGS. 2-9 also include experimental results of averages and standard deviations of the surface roughness of the different surface finishes specifically: arithmetical mean height (Sa) in micrometers (μm)), root mean square height (Sq) in micrometers, maximum height (Sz) of surface roughness in micrometers, and developed interfacial area ratio (Sdr) as a percentage (%).

FIG. 10 includes a table combining the experimental results of the averages and standard deviations of the surface roughness of the different surface finishes shown in FIGS. 2-9.

### DETAILED DESCRIPTION

Example embodiments will now be described more fully with reference to the accompanying drawings.

Consumer electronics often have oil bleed (broadly, migration of materials) from thermal interface composite materials. And this oil bleed can sometimes interfere with workings of electronic packages or devices and/or cause aesthetic issues. Although conventional methods exist to reduce bleed from thermal management and/or electromagnetic interference (EMI) mitigation materials (e.g., a TIM, etc.) by changing their formulations, such conventional methods often have been found to significantly increase hardness such that the harder material is not able to readily deflect under low levels of applied force.

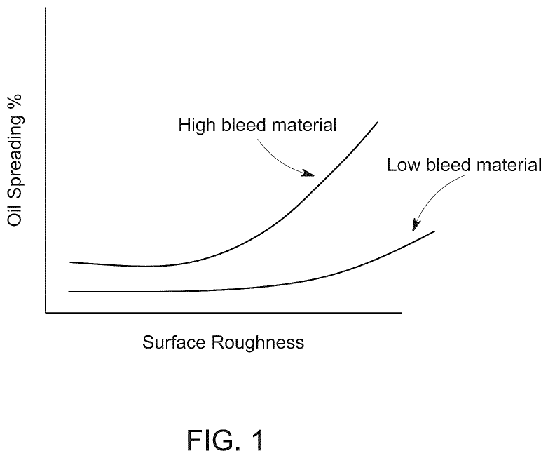

As recognized herein and shown in FIG. 1, oil bleed spreading percentage decreases as the surface roughness decreases. Accordingly, the inventors hereof developed and/or disclose herein exemplary methods for reducing the spreading of material(s) migrating (e.g., reducing oil bleed spreading, etc.) from a composite without having to change a formulation of the composite. The reduction in oil bleed advantageously allows for the continued use of thermal management and/or electromagnetic interference (EMI) mitigation materials that currently bleed, which oil bleed might otherwise interfere with the workings of electronic packages or devices and/or cause aesthetic issues.

As disclosed herein, exemplary methods include configuring or providing a component (e.g., an electronic device component, etc.) with a surface having a surface roughness characterized by at least one or both of: an arithmetical mean height (Sa) no greater than about 1.25 micrometers and a root mean square height (Sq) no greater than about 1.5 micrometers. The surface having the surface roughness is usable for reducing the spreading of material(s), if any, migrating from a composite along the surface.

Also disclosed are exemplary methods for reducing the spreading of material(s) migrating (e.g., reducing oil bleed spreading, etc.) from a composite by positioning the composite directly on and/or adjacent (e.g., within a perimeter defined by, etc.) a surface having a surface roughness characterized by at least one or both of: an arithmetical mean height (Sa) no greater than about 1.25 micrometers and a root mean square height (Sq) no greater than about 1.5 micrometers.

The surface having the surface roughness for reducing oil bleed spreading may be defined by or provided along a component, an assembly, and/or a portion of an electronic device (e.g., solid-state device, etc.). For example, the surface may be defined by or provided along a heat removal/dissipation structure such as a heat sink, a heat spreader, a heat pipe, a vapor chamber, a device exterior case, housing, or chassis. Or, for example, the surface may be defined by or provided along a heat source of an electronic device, such as an integrated circuit or other component of the electronic device. As yet another example, the surface may be defined by or provided along a board level shield. The surface having the surface roughness for reducing oil bleed spreading may comprise a shiny/smooth/glossy area(s) or material(s), a glossy painted surface, a mirror surface, a sandblasted surface, a plasma etched surface, a plated surface, a combination thereof, etc.

As recognized herein, a problem that needs to be solved is that when a mobile phase exudes from a thermal interface material (TIM) (broadly, a composite) inside an assembly, the mobile material can flow along the surface until it reaches a physical edge. The mobile phase can flow to the edge of a substrate that is part of the assembly, and around the edge of that part onto the opposite surface. One example is the physical edge of a heat sink. In the case of a heat sink where the bottom surface is in contact with a TIM, the mobile phase can flow along the underside of the heat sink, around the edge, and eventually cover the top surface of the heat sink, perhaps including the fins. In this exemplary embodiment, having a smooth surface (e.g., smooth and/or glossified metal surface, etc.) on the underside of the heat sink will prevent the transport of the mobile phase.

In another exemplary embodiment, the underside of the heat sink can be patterned with a smooth finish around the perimeter, while the internally proscribed region can have a matte finish. In another exemplary embodiment, the side of the heat sink can be manufactured to have a smooth finish. Then the mobile phase will travel to the edge of the heat sink, but not up the sides.

A second kind of physical edge is an open hole in the middle of the substrate. In this circumstance, the mobile phase starts on one side of a multicomponent assembly, and appears on the opposite side of the assembly, by bleeding through the hole. If the perimeter of the hole has a smooth finish on the face of the substrate, the mobile phase will not pass through the hole. This perimeter can be on the face of the substrate. Alternatively, the perimeter may be defined as the vertical inside wall of the hole that is contiguous with the top and bottom surfaces. If that vertical inside wall has a smooth finish, the mobile phase will not be able to pass from the top to the bottom surface.

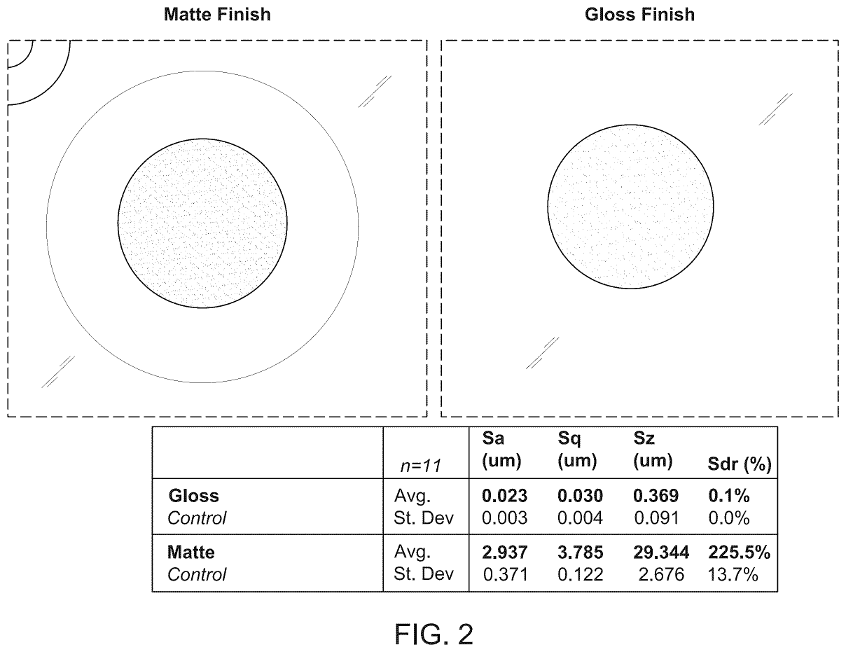

FIGS. 2 through 9 include color photographs showing oil bleed spreading from two materials along different surface finishes having different surface roughness. FIGS. 2-9 also include experimental results of averages and standard deviations of the surface roughness of the different surface finishes specifically: arithmetical mean height (Sa) in micrometers (μm)), root mean square height (Sq) in micrometers, maximum height (Sz) of surface roughness in micrometers, and developed interfacial area ratio (Sdr) as a percentage (%). As experimentally demonstrated in FIGS. 2-9, oil bleed spreading decreases as the surface roughness decreases.

By way of background, arithmetical mean height (Sa) is the mean of the absolute value of the height of points within the defined area. Arithmetical mean height (Sa) is used to generally evaluate surface roughness.

$$Sa = \frac{1}{A} \int {\int }_{A} \vert Z ( x , y ) \vert dxdy$$

Root mean square height (Sq) represents the root mean square value of ordinate values within the defined area. Root mean square height (Sq) is equivalent to the standard deviation of heights.

$$Sq = \sqrt{\frac{1}{A} \int {\int }_{A} \vert {Z}^{2} ( x , y ) dxdy}$$

Developed interfacial area ratio (Sdr) is expressed as the percentage of the defined area's additional surface area contributed by the texture as compared to a planar defined area.

FIG. 2 includes color photographs showing oil bleed spreading from a first thermal interface material along a matte surface finish (e.g., ultra flat black painted surface) and oil bleed spreading from the first thermal interface material along a glossy surface finish (e.g., gloss black painted surface). As shown in FIG. 2, the oil bleed spreading from the first thermal interface material was significantly higher and worse when the first thermal interface material was along the matte surface finish as compared to the glossy surface finish.

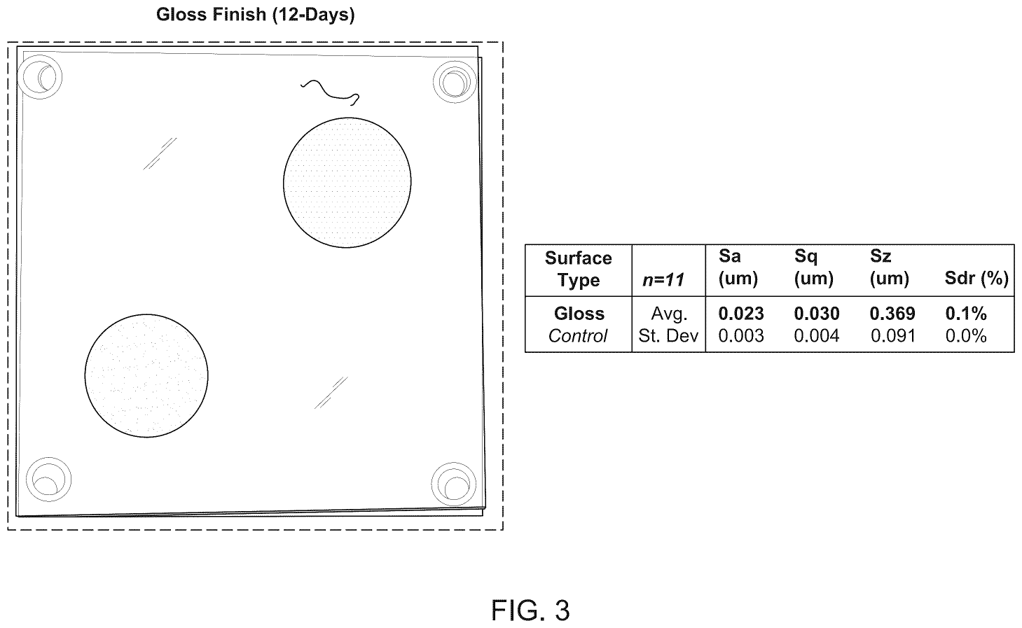

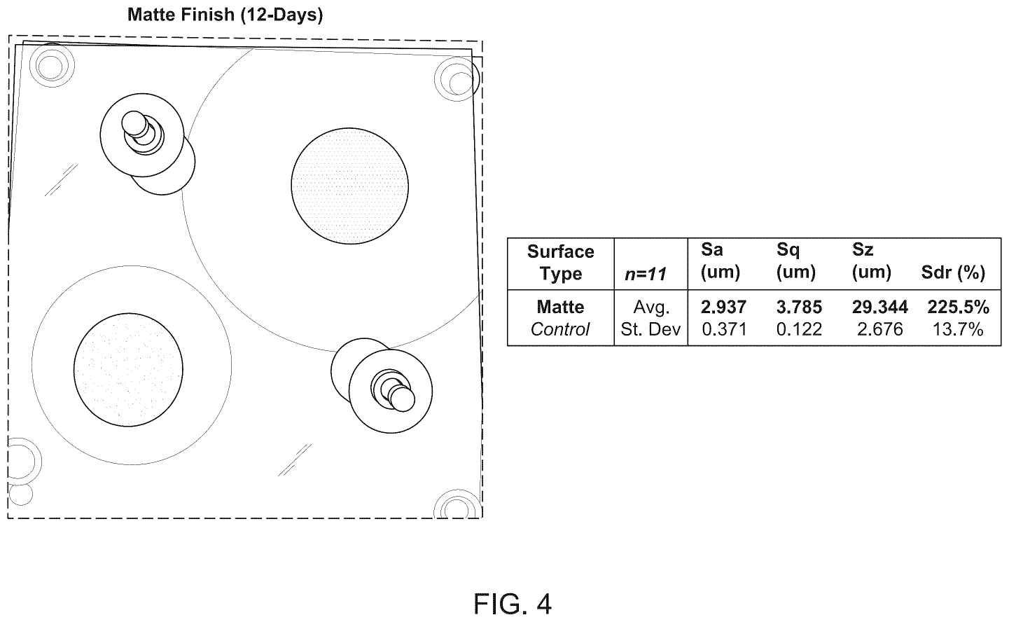

FIG. 3 includes a color photograph showing oil bleed spreading from first and second thermal interface materials along a gloss finish (e.g., gloss black painted surface) after 12 days. FIG. 4 includes a color photograph showing oil bleed spreading from the first and second thermal interface materials along a matte finish (e.g., ultra flat black painted surface) after 12 days. A comparison of FIGS. 3 and 4 reveals that the oil bleed spreading from the first and second thermal interface materials along the gloss finish (FIG. 3) was significantly reduced and improved as compared to the oil bleed spreading from the first and second thermal interface materials along the matte finish (FIG. 4).

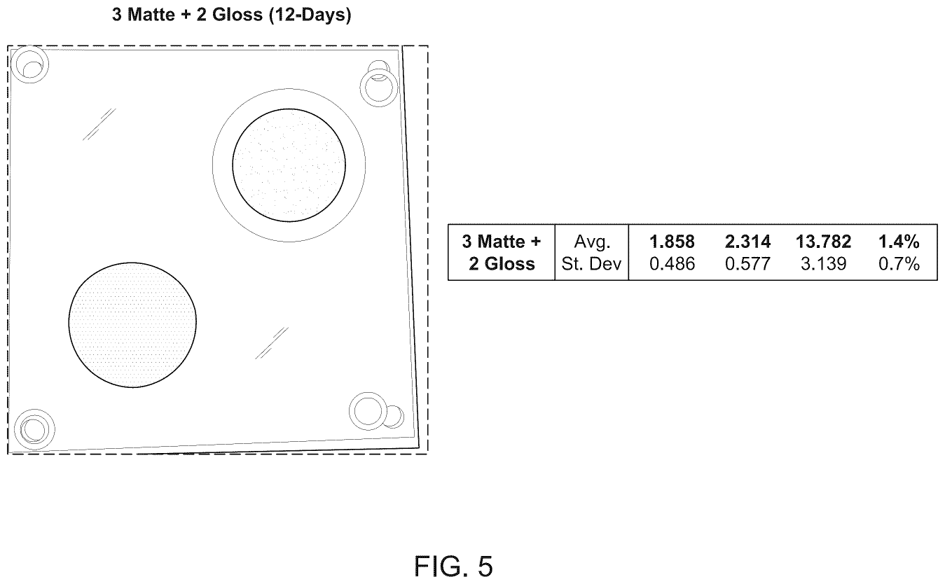

FIG. 5 includes a color photograph showing oil bleed spreading from the first and second thermal interface materials along a 3 Matte+2 Gloss surface finish after 12 days. For this example, the surface included 3 coats of Matte paint first and then 2 coats of Gloss paint on top of the Matte paint.

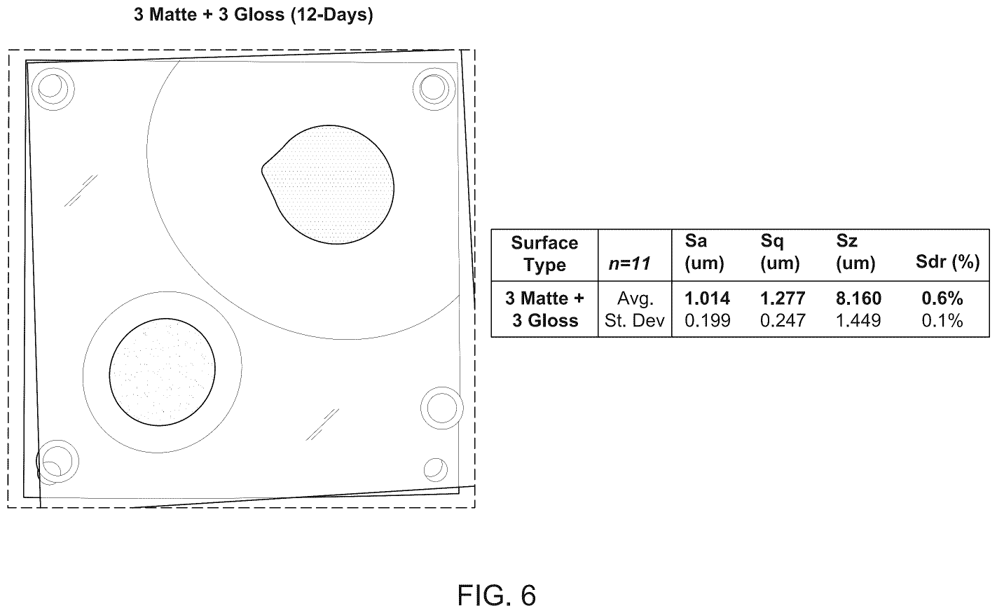

FIG. 6 includes a color photograph showing oil bleed spreading from the first and second thermal interface materials along a 3 Matte+3 Gloss surface finish after 12 days. For this example, the surface included 3 coats of Matte paint first and then 3 coats of Gloss paint on top of the Matte paint.

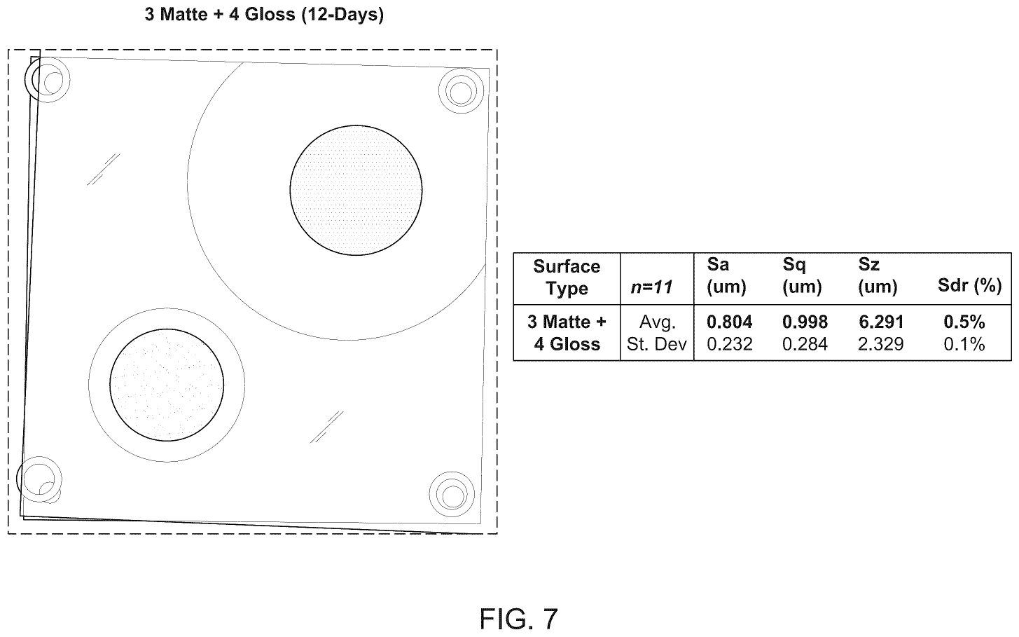

FIG. 7 includes a color photograph showing oil bleed spreading from the first and second thermal interface materials along a 3 Matte+4 Gloss surface finish after 12 days. For this example, the surface included 3 coats of Matte paint first and then 4 coats of Gloss paint on top of the Matte paint.

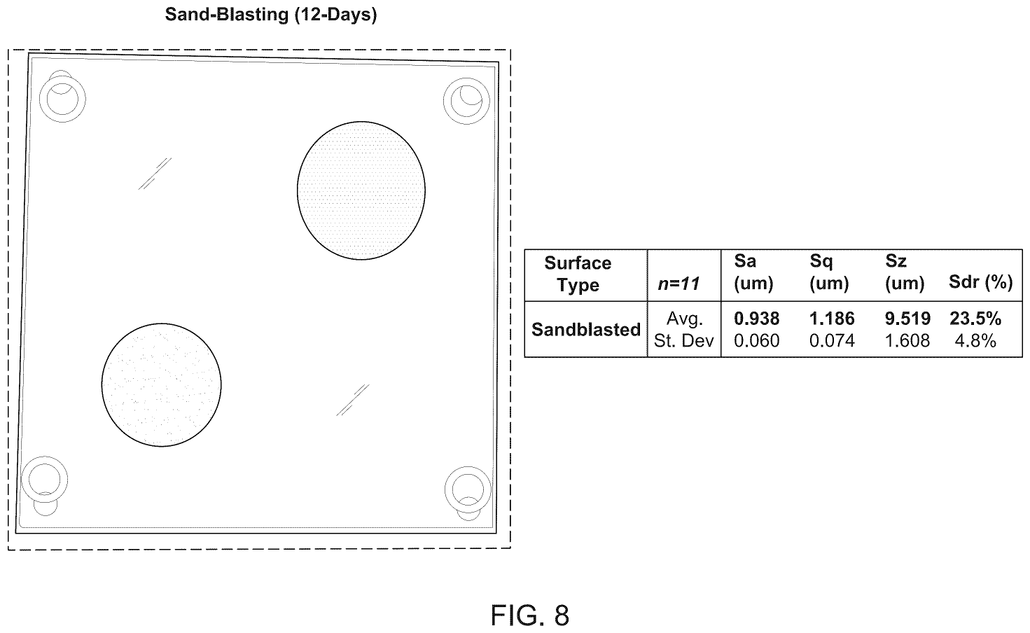

FIG. 8 includes a color photograph showing oil bleed spreading from the first and second thermal interface materials along a sandblasted surface (e.g., having an arithmetical mean height (Sa) of about 1 micrometer or less, etc.) after 12 days.

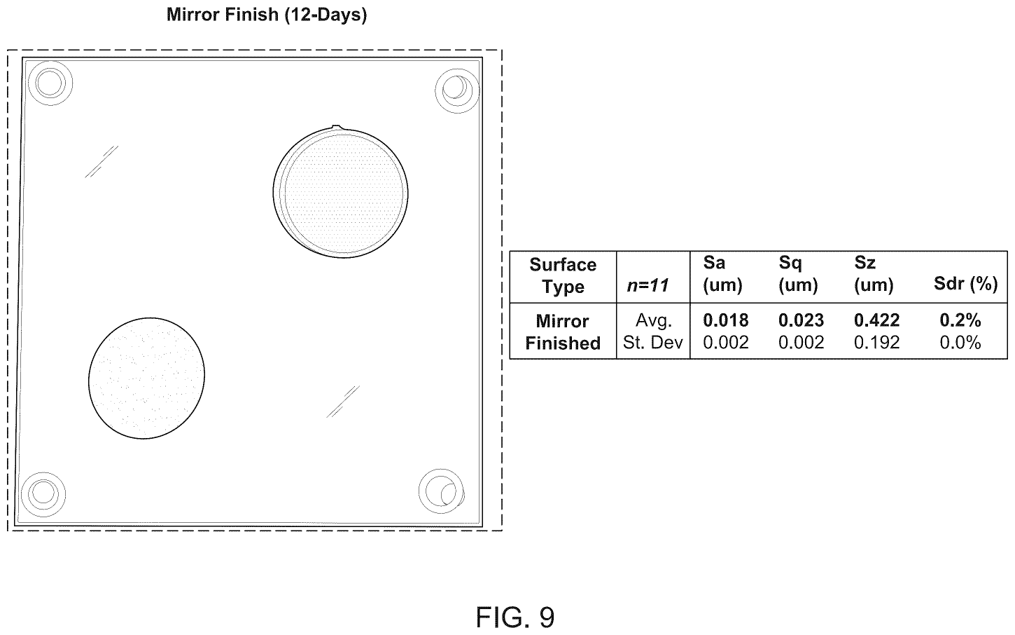

FIG. 9 includes a color photograph showing oil bleed spreading from the first and second thermal interface materials along a mirror finish after 12 days.

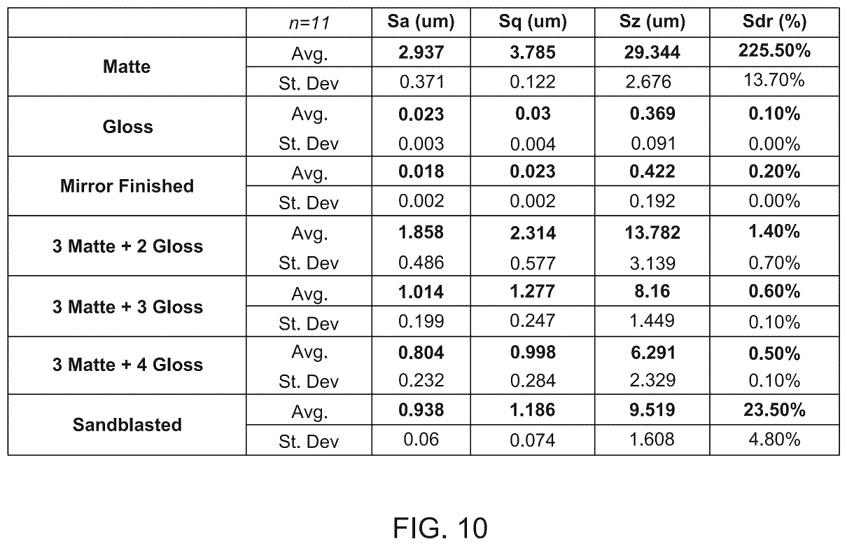

FIG. 10 includes a table combining the experimental results of the averages and standard deviations of the surface roughness of the different surface finishes shown in FIGS. 2-9.

In FIGS. 2-9, the first thermal interface material is the blue colored material in the lower left corner, and the second thermal interface material is the grey colored material in the upper right corner. By way of example only, the second thermal interface material was a silicone-based thermal grease, and the first thermal interface material was single part ceramic filled silicone dispensable thermal putty. But these specific first and second thermal interface materials are examples only as aspects of the present disclosure are applicable to other thermal management and/or electromagnetic interference (EMI) mitigation materials (e.g., thermal interface materials (TIMs), EMI absorbers, thermally-conductive EMI absorbers, electrically-conductive elastomers (ECEs), electrically-conductive composites, combinations thereof, etc.) and other polymer-inorganic composite materials used for other purposes.

Similar benefits of reducing oil bleed spreading are expected for other thermal interface materials (TIMs), thermal management and/or electromagnetic interference (EMI) mitigation materials, and other polymer-inorganic composite materials used for other purposes, which have the potential to bleed. Accordingly, this invention will have wide applicability to a wide range of thermal interface materials (TIMs), thermal management and/or electromagnetic interference (EMI) mitigation materials, and other polymer-inorganic composite materials used for other purposes, in which it would be desirable to have reduced spreading of material(s) migrating (e.g., migration of organic species, oil bleed, etc.) from at composite to locations external to the composite. In addition, exemplary embodiments disclosed herein may be used in a wide range of industries (e.g., automotive, consumer, industrial, datacom/telecom, aerospace/defense, etc.) and wide range of applications (e.g., automotive electronics, automotive advanced driver-assistance systems (ADAS), automotive powertrain/electronic control units (ECUs), automotive infotainment, industrial power, routers, wireless infrastructure, drones/satellites, gaming systems, smart home devices, notebooks/tablets/portable devices, etc.).

It is challenging to balance the preparation of a highly-loaded polymer composite for use as a thermal management and/or EMI mitigation material that has the ability to fulfill the desired thermal management and/or EMI mitigation requirements and other requirements while also readily deflecting under low levels of applied force. In these materials, oil bleeding may result for multiple reasons. For example, conventional thermal management and/or EMI mitigation materials are commonly based on the use of silicone polymers. Silicone polymers typically contain a wide distribution of molecular weight (MW) polymers. It is commonly assumed that some of the polymer with low molecular weights are capable of migration in the matrix to such an extent that the migrated polymer materials become visibly apparent beyond the confines of the composite, thereby resulting in undesirable aesthetics. Other additives in the composite in addition to the silicone polymers, such as dispersing agents, stabilizing agents (e.g., UV stabilizers, thermal stabilizers, etc.) and the like, may also migrate. Composites that use polymers that are not based on silicone materials also contain species capable of migration, and face similar challenges as described above for representative silicone-based systems.

But as disclosed herein, the spreading of material(s) migrating (e.g., reducing oil bleed spreading, etc.) from a composite may be reduced without having to change a formulation of the composite. This is significant in that oil bleed is a concern for aesthetic reasons as well as due to the potential contamination of optics in electronic applications (e.g., optical transceivers, camera lenses, etc.), such as high speed signal lines that may otherwise be affected by oil bleed. Exemplary embodiments may advantageously stop or inhibit oil bleed spreading along a device casing or housing, which oil bleed might otherwise not be aesthetically pleasing.

Disclosed are exemplary methods for reducing the spreading of material(s), if any, migrating from a composite without having to change a formulation of the composite. An exemplary method includes positioning the composite relative to a surface having a surface roughness configured for reducing the spreading of material(s), if any, migrating from the composite along the surface. The surface roughness is characterized by at least one or both of: an arithmetical mean height (Sa) no greater than about 1.25 micrometers and a root mean square height (Sq) no greater than about 1.5 micrometers.

Also disclosed are exemplary methods relating to reducing the spreading of material(s), if any, migrating from a composite without having to change a formulation of the composite. An exemplary method includes configuring a surface to have a surface roughness characterized by at least one or both of an arithmetical mean height (Sa) no greater than about 1.25 micrometers and a root mean square height (Sq) no greater than about 1.5 micrometers. The surface having the surface roughness is usable for reducing the spreading of material(s), if any, migrating from a composite along the surface.

An exemplary method includes positioning a composite on and/or adjacent a surface that has been smoothed and/or glossified to have a surface roughness for reducing the spreading of material(s), if any, migrating from the composite along the surface.

An exemplary method includes smoothing and/or glossifying a surface to have a surface roughness for reducing the spreading of material(s), if any, migrating from a composite along the surface.

In exemplary methods, the surface roughness is characterized by at least one or both of an arithmetical mean height (Sa) no greater than about 1.25 micrometers and a root mean square height (Sq) no greater than about 1.5 micrometers.

In exemplary methods, the surface roughness is further characterized by a developed interfacial area ratio (Sdr) no greater than about 250%.

In exemplary methods, the surface roughness is characterized by at least one or both of an arithmetical mean height (Sa) from about 0.01 micrometers (μm) to about 1.25 (μm) and a root mean square height (Sq) from about 0.01 micrometers to about 1.5 micrometers.

In exemplary methods, the surface roughness is further characterized by a developed interfacial area ratio (Sdr) from about 0.1% to about 250%.

In exemplary methods, the method includes reducing the spreading of material(s), if any, migrating from the composite along the surface without changing the formulation of the composite.

In exemplary methods, the composite is useful for the management of heat and/or electromagnetic interference (EMI).

In exemplary methods, the surface is configured to have a minimum thickness sufficient to decrease a surface roughness of an underlying component to at least one or both of an arithmetical mean height (Sa) no greater than about 1.25 micrometers and a root mean square height (Sq) no greater than about 1.5 micrometers. The surface may have a minimum thickness that is needed to bring down the surface roughness (Sa) to no greater than 1.25 micrometers. For example, if a heat sink has a surface roughness of 1.75 micrometers, then only 0.5 micrometers of paint thickness may be needed to bring down the surface roughness (Sa) to 1.25 micrometers. The underlying component may comprise one or more of: a heat removal/dissipation structure such as a heat sink, a heat spreader, a heat pipe, a vapor chamber, a device exterior case, housing, or chassis; a heat source of an electronic device, such as an integrated circuit or other component of the electronic device; a solid-state drive; and/or a board level shield.

In exemplary methods, the method includes configuring the surface to have a surface roughness for reducing the spreading of material(s), if any, migrating from a composite along the surface by one or more of: glossifying the surface; transforming the surface to have a glossy, mirrored, shiny, and/or polished appearance; polishing the surface; painting the surface; coating the surface; sandblasting the surface; plasma etching the surface; plating the surface; and/or transforming the surface to have the surface roughness characterized by at least one an arithmetical mean height (Sa) no greater than about 1.25 micrometers and a root mean square height (Sq) no greater than about 1.5 micrometers.

In exemplary methods, the method includes configuring the surface to have a surface roughness for reducing the spreading of material(s), if any, migrating from the composite along the surface. After configuring the surface, the method includes: positioning the composite directly on the surface such that the surface is operable for reducing the spreading of material(s), if any, migrating from the composite along the surface; positioning the composite adjacent to the surface such that the surface is operable for reducing the spreading of material(s), if any, migrating from the composite along the surface; and/or positioning the composite along a second surface opposite the surface such that the surface is operable for reducing the spreading along the second surface of any material(s) migrating from the composite along the surface.

In exemplary methods, the surface has a minimum width of at least about 5 micrometers.

In exemplary methods, the method includes positioning the composite directly on the surface such that the surface is directly underneath and in contact with the composite.

In exemplary methods, the method includes positioning the composite relative to the surface such that the surface is disposed generally around the composite.

In exemplary methods, the method includes positioning the composite within a perimeter defined by the surface such that the composite is disposed entirely within and/or surrounded by the surface.

In exemplary methods, the method includes positioning the composite along a second surface opposite the surface, whereby the surface is operable for reducing the spreading along the second surface of any material(s) migrating from the composite along the surface.

In exemplary methods, the surface having the surface roughness for reducing the spreading of material(s) is a first surface. And the method includes positioning the composite along a second surface opposite the first surface, whereby the first surface is operable for reducing the spreading along the first surface of any material(s) migrating from the composite along the second surface to the first surface. For example, a heat sink (broadly, a component) may include a bottom surface (broadly, a first surface) and an opposite top surface (broadly, a second surface). The bottom surface of the heat sink may be configured to have a surface roughness (e.g., an arithmetical mean height (Sa) no greater than about 1.25 micrometers and/or a root mean square height (Sq) no greater than about 1.5 micrometers, etc.) for reducing the spreading of material(s). The composite (e.g., a TIM 1.5 packaging on top of a chip, etc.) may be positioned along the top surface of the heat sink. In this example, the bottom surface of the heat sink may be operable for preventing (or at least reducing) the spreading along the bottom surface of material(s) that are migrating from the composite along the top surface. For example, material(s) migrating from the composite along the second surface may migrate around the sides of the heat sink and/or through openings (e.g., screw holes, ventilation holes, etc.) in the heat sink. In which case, the bottom surface of the heat sink may reduce or stop the spreading of the materials along the bottom surface that migrated around the sides of the heat sink and/or through the openings of the heat sink.

In exemplary embodiments, a second surface of a component to which material(s) may migrate from a component on an opposite first surface may be configured (e.g., smoothed and/or glossified, etc.) to have a surface roughness (e.g., an arithmetical mean height (Sa) no greater than about 1.25 micrometers and/or a root mean square height (Sq) no greater than about 1.5 micrometers, etc.) for reducing the spreading along the second surface of material(s) migrating from the composite along the first surface.

In exemplary embodiments, a heat sink may be provided with or configured to have a polished, smoothed, and/or glossified perimeter surface that is disposed or extends around the perimeter of a composite (e.g., TIM 1.5, etc.) to prevent bleeding around the heat sink to the underside of the heat sink.

In exemplary embodiments, the surface having the surface roughness (e.g., an arithmetical mean height (Sa) no greater than about 1.25 micrometers and/or a root mean square height (Sq) no greater than about 1.5 micrometers, etc.) can be one of, any combination of, or all of:
a surface directly underneath the composite on which the composite is placed/dispensed; and/or
a surface adjacent to, disposed around, and/or defining a perimeter around the composite; and/or
a second surface (e.g., of a heat sink, other component, etc.) opposite the surface along which the composite is placed and/or to which the material/bleed could migrate to, whereby the opposite second surface may be operable for reducing spreading along the opposite second surface of materials migrating from the composite along the first surface to the opposite second surface.

In exemplary methods, the surface is operable for reducing the spreading of material(s), if any, migrating from the composite along the surface such that the composite is usable substantially or entirely without material migration along the surface beyond confines of the composite.

In exemplary methods, the surface is operable for reducing the spreading of silicone oil bleed from the composite along the surface. In which case, the composite may then be usable substantially or entirely without silicone migration beyond confines of the composite.

In exemplary methods, the surface is operable for reducing the spreading of non-silicone oil bleed and/or hydrocarbon oil bleed from the composite along the surface. In which case, the composite may then be usable substantially or entirely without non-silicone oil bleed and/or hydrocarbon oil bleed migrating beyond confines of the composite.

In exemplary methods, the method includes dispensing the composite on the surface, adjacent to the surface, and/or on a second surface opposite the surface after configuring the surface to have a surface roughness characterized by at least one or both of: an arithmetical mean height (Sa) no greater than about 1.25 micrometers and a root mean square height (Sq) no greater than about 1.5 micrometers.

In exemplary methods, the method includes configuring a component of an electronic device to have the surface with the surface roughness for reducing the spreading of material(s), if any, migrating from the composite along the surface of the component of the electronic device.

In exemplary methods, a component or assembly of an electronic device includes the surface having the surface roughness for reducing the spreading of material(s), if any, migrating from the composite along the surface. And the method includes positioning the composite on the surface, adjacent to the surface, and/or on a second surface opposite to the surface of the component or assembly of the electronic device that has been configured to have the surface roughness for reducing the spreading of material(s), if any, migrating from the composite along the surface of the component or assembly of the electronic device. The component or assembly of the electronic device may comprise one or more of: a heat removal/dissipation structure such as a heat sink, a heat spreader, a heat pipe, a vapor chamber, a device exterior case, housing, or chassis; a heat source of an electronic device, such as an integrated circuit or other component of the electronic device; a component of a solid-state drive; and/or a board level shield.

In exemplary methods, a heat sink or other component includes a bottom surface having the surface roughness for reducing the spreading of material(s), if any, migrating from the composite along the bottom surface of the heat sink or other component. And the method includes positioning the composite on a top surface of the heat sink or other component such that the bottom surface is operable for reducing the spreading along the bottom surface of any material(s) migrating from the composite along the top surface to the bottom surface.

In exemplary methods, a heat sink or other component includes a top surface having the surface roughness for reducing the spreading of material(s), if any, migrating from the composite along the top surface of the heat sink or other component. And the method includes positioning the composite on a bottom surface of the heat sink or other component such that the top surface is operable for reducing the spreading along the top surface of any material(s) migrating from the composite along the bottom surface to the top surface.

In exemplary methods, the composite comprises one or more of: thermally-conductive filler(s); electrically-conductive filler(s); electromagnetic wave absorbing filler(s); dielectric absorbing filler(s); and filler(s) that has two or more properties of being thermally conductive, electrically conductive, dielectric absorbing, and electromagnetic wave absorbing.

In exemplary methods, the composite is a thermal phase change material, a thermal putty, a thermal grease, a dispensable thermal interface material, and/or a thermal gap filler pad.

In exemplary methods, the composite is a silicone-based thermal grease or a single part ceramic filled silicone dispensable material.

In exemplary methods, the composite is a thermal interface material, an EMI absorber, a thermally-conductive absorber, an electrically-conductive elastomer, an electrically-conductive composite, or a combination of two or more thereof.

In exemplary methods, the method includes smoothing and/or glossifying surface(s) at location(s) at which typical bleed may occur such that the smoothed and/or glossified surface(s) at those location(s) have the surface roughness for reducing the spreading of material(s), if any, migrating from the composite along the smoothed and/or glossified surface(s)

In exemplary methods, the method includes smoothing and/or glossifying a surface of a substrate having a hole that extends between top and bottom surfaces of a substrate, such that the smoothed and/or glossified surface is operable for reducing the spreading through the hole of material(s) migrating from the composite. The smoothed and/or glossified surface may define a perimeter around the hole along the top or bottom surface of the substrate. Additionally, or alternatively, the smoothed and/or glossified surface may be along and/or define one or more vertical interior walls of the hole.

In exemplary methods, the surface having the surface roughness for reducing the spreading of material(s), if any, migrating from the composite comprises at least one of: a surface defining a perimeter around a hole that extends between top and bottom surfaces; and/or a surface defining one or more vertical interior walls of the hole. The surface having the surface roughness is operable for reducing the spreading through the hole of material(s) migrating from the composite.

Also disclosed are exemplary embodiments in which a component or assembly is configured to have a surface with a surface roughness operable for reducing the spreading of material(s), if any, migrating from a composite along the surface, wherein the composite is useful for the management of heat and/or electromagnetic interference (EMI).

In exemplary embodiments, the surface roughness is characterized by at least one or both of: an arithmetical mean height (Sa) no greater than about 1.25 micrometers and a root mean square height (Sq) no greater than about 1.5 micrometers. The surface roughness may also be characterized by a developed interfacial area ratio (Sdr) no greater than about 250%.

In exemplary embodiments, the surface roughness is characterized by at least one or both of: an arithmetical mean height (Sa) from about 0.01 micrometers (μm) to about 1.25 (μm) and a root mean square height (Sq) from about 0.01 micrometers to about 1.5 micrometers. The surface roughness may also be characterized by a developed interfacial area ratio (Sdr) from about 0.1% to about 250%.

In exemplary embodiments, the surface is configured with the surface roughness operable for reducing the spreading of material(s), if any, migrating from the composite along the surface without changing the formulation of the composite.

In exemplary embodiments, the component or assembly comprises one or more of: a heat removal/dissipation structure such as a heat sink, a heat spreader, a heat pipe, a vapor chamber, a device exterior case, housing, or chassis; a heat source of an electronic device, such as an integrated circuit or other component of the electronic device; a component of a solid-state drive; and/or a board level shield.

In exemplary embodiments, the surface comprises one or more of: a glossified surface; a surface having a glossy, mirrored, shiny, and/or polished appearance; a polished surface; a painted surface; a coated surface; a sandblasted surface; a plasma etched surface; and/or a plated surface.

In exemplary embodiments, the surface has a minimum width of at least about 5 micrometers.

In exemplary embodiments, the surface is configured with the surface roughness operable for reducing the spreading of material(s), if any, migrating from the composite along the surface such that the composite is usable substantially or entirely without material migration along the surface beyond confines of the composite.

In exemplary embodiments, the surface is configured with the surface roughness operable for reducing the spreading of silicone oil bleed from the composite along the surface. In which case, the composite may be usable substantially or entirely without silicone migration beyond confines of the composite.

In exemplary embodiments, the surface is configured with the surface roughness operable for reducing the spreading of non-silicone oil bleed and/or hydrocarbon oil bleed from the composite along the surface. In which case, the composite may be usable substantially or entirely without non-silicone oil bleed and/or hydrocarbon oil bleed migration beyond confines of the composite.

In exemplary embodiments, the component or assembly includes a bottom surface and a top surface opposite the bottom surface. The bottom surface is configured to have the surface roughness operable for reducing the spreading along the bottom surface of any material(s) migrating from a composite along the top surface to the bottom surface.

In exemplary embodiments, the component or assembly includes a bottom surface and a top surface opposite the bottom surface. The top surface is configured to have the surface roughness operable for reducing the spreading along the top surface of any material(s) migrating from a composite along the bottom surface to the top surface.

In exemplary embodiments, the component or assembly comprises a heat sink including a bottom surface and a top surface opposite the bottom surface. The bottom surface is configured to have the surface roughness operable for reducing the spreading along the bottom surface of any material(s) migrating from a composite along the top surface to the bottom surface.

In exemplary embodiments, the component or assembly comprises a heat sink including a bottom surface and a top surface opposite the bottom surface. The top surface is configured to have the surface roughness operable for reducing the spreading along the top surface of any material(s) migrating from a composite along the bottom surface to the top surface.

In exemplary embodiments, the component or assembly comprises a top surface, a bottom surface, and a hole extending between the top and bottom surfaces. The surface having the surface roughness is configured to be operable for reducing the spreading through the hole of material(s) migrating from a composite. The surface having the surface roughness for reducing the spreading through the hole of material(s) migrating from a composite may comprise at least one: a surface defining a perimeter around the hole; and/or a surface defining one or more vertical interior walls of the hole.

In exemplary embodiments, the component or assembly comprises a composite, which may be useful for the management of heat and/or electromagnetic interference (EMI). The surface is operable for reducing the spreading of material(s), if any, migrating from the composite along the surface.

In exemplary embodiments, the composite is directly on the surface such that the surface is directly underneath and in contact with the composite.

In exemplary embodiments, the surface is disposed generally around the composite.

In exemplary embodiments, the composite is within a perimeter defined by the surface such that the composite is disposed entirely within and/or surrounded by the surface.

In exemplary embodiments, the composite is along a second surface opposite the surface. The surface is operable for reducing the spreading along the second surface of any material(s) migrating from the composite along the surface.

In exemplary embodiments, the composite comprises one or more of: thermally-conductive filler(s); electrically-conductive filler(s); electromagnetic wave absorbing filler(s); dielectric absorbing filler(s); and filler(s) that has two or more properties of being thermally conductive, electrically conductive, dielectric absorbing, and electromagnetic wave absorbing.

In exemplary embodiments, the composite is a thermal phase change material, a thermal putty, a thermal grease, a dispensable thermal interface material, and/or a thermal gap filler pad.

In exemplary embodiments, the composite is a silicone-based thermal grease or a single part ceramic filled silicone dispensable material.

In exemplary embodiments, the composite is a thermal interface material, an EMI absorber, a thermally-conductive absorber, an electrically-conductive elastomer, an electrically-conductive composite, or a combination of two or more thereof.

In exemplary embodiments, the component or assembly comprises one or more of: a heat removal/dissipation structure such as a heat sink, a heat spreader, a heat pipe, a vapor chamber, a device exterior case, housing, or chassis; a heat source, such as an integrated circuit or other heat generating component of the device; a component of a solid-state drive; and/or a board level shield.

In an exemplary embodiments, an electronic device includes a heat source and a thermally-conductive composite (e.g., thermal grease, thermal putty, other thermal interface material, etc.). The thermally-conductive composite is positioned relative to the heat source for establishing at least a portion of a thermally-conductive heat path from the heat source through the composite. The thermally-conductive composite is also positioned relative to (e.g., on, in contact with, within a perimeter defined by, etc.) a surface along and/or of the electronic device that has been configured (e.g., painted, coated, sandblasted, etc.) to have a surface roughness (e.g., as shown in any one or more of FIGS. 1-10, etc.) for reducing the spreading of material(s), if any, migrating from the thermally-conductive composite along the surface. The surface roughness may be characterized as having one or more of: an arithmetical mean height (Sa) no greater than about 1.25 (μm) (e.g., an arithmetical mean height (Sa) from about 0.01 micrometers (μm) to about 1.25 (μm), etc.); a root mean square height (Sq) no greater than about 1.5 micrometers (e.g., root mean square height (Sq) from about 0.01 micrometers to about 1.5 micrometers, etc.), and a developed interfacial area ratio (Sdr) no greater than about 250%. (e.g., a developed interfacial area ratio (Sdr) from about 0.1% to about 250%, etc.). In such exemplary embodiments, the thermally-conductive composite may also be configured to be EMI absorbing and/or electrically conductive, such that the composite is also operable for mitigating and/or managing EMI within the electronic device.

In an exemplary embodiment, an electronic device includes a heat source, a heat removal/dissipation structure, and a thermally-conductive composite (e.g., thermal grease, thermal putty, other thermal interface material, etc.). The thermally-conductive composite is positioned relative to the heat source and the heat removal/dissipation structure for establishing at least a portion of a thermally-conductive heat path between the heat source and the heat removal/dissipation structure. The thermally-conductive composite is also positioned relative to (e.g., on, in contact with, within a perimeter defined by, etc.) a surface along and/or of the electronic device and/or heat removal/dissipation structure, wherein that surface has been configured (e.g., painted, coated, sandblasted, etc.) to have a surface roughness (e.g., as shown in any one or more of FIGS. 1-10, etc.) for reducing the spreading of material(s), if any, migrating from the thermally-conductive composite along the surface. The surface roughness may be characterized as having one or more of: an arithmetical mean height (Sa) no greater than about 1.25 (μm) (e.g., an arithmetical mean height (Sa) from about 0.01 micrometers (μm) to about 1.25 (μm), etc.); a root mean square height (Sq) no greater than about 1.5 micrometers (e.g., root mean square height (Sq) from about 0.01 micrometers to about 1.5 micrometers, etc.), and a developed interfacial area ratio (Sdr) no greater than about 250%. (e.g., a developed interfacial area ratio (Sdr) from about 0.1% to about 250%, etc.). The thermally-conductive composite may be configured to be EMI absorbing and/or electrically conductive, such that the composite is also operable for mitigating and/or managing EMI within the electronic device.

In an exemplary embodiment, an electronic device includes a heat source, a board level shield, and a thermally-conductive composite (e.g., thermal grease, thermal putty, other thermal interface material, etc.). The thermally-conductive composite is positioned relative to the heat source and the board level shield for establishing at least a portion of a thermally-conductive heat path between the heat source and the board level shield. The thermally-conductive composite is also positioned relative to (e.g., on, in contact with, within a perimeter defined by, etc.) a surface along and/or of the electronic device and/or board level shield, wherein that surface has been configured (e.g., painted, coated, sandblasted, etc.) to have a surface roughness (e.g., as shown in any one or more of FIGS. 1-10, etc.) for reducing the spreading of material(s), if any, migrating from the thermally-conductive composite along the surface. The surface roughness may be characterized as having one or more of: an arithmetical mean height (Sa) no greater than about 1.25 (μm) (e.g., an arithmetical mean height (Sa) from about 0.01 micrometers (μm) to about 1.25 (μm), etc.); a root mean square height (Sq) no greater than about 1.5 micrometers (e.g., root mean square height (Sq) from about 0.01 micrometers to about 1.5 micrometers, etc.), and a developed interfacial area ratio (Sdr) no greater than about 250%. (e.g., a developed interfacial area ratio (Sdr) from about 0.1% to about 250%, etc.). The thermally-conductive composite may be configured to be EMI absorbing and/or electrically conductive, such that the composite is also operable for mitigating and/or managing EMI within the electronic device.

In an exemplary embodiment, an electronic device includes a heat source, a board level shield, a heat removal/dissipation structure, and first and second thermally-conductive composites (e.g., thermal grease, thermal putty, other thermal interface material, etc.). The first thermally-conductive composite is positioned relative to the heat source and the board level shield for establishing at least a portion of a first thermally-conductive heat path between the heat source and the board level shield. The second thermally-conductive composite is positioned relative to the board level shield and the heat removal/dissipation structure for establishing at least a portion of a second thermally-conductive heat path between the board level shield and the heat removal/dissipation structure. The first thermally-conductive composite is also positioned relative to (e.g., on, in contact with, within a perimeter defined by, etc.) a first surface along and/or of the electronic device and/or board level shield, which first surface has been configured (e.g., painted, coated, sandblasted, etc.) to have a surface roughness (e.g., as shown in any one or more of FIGS. 1-10, etc.) for reducing the spreading of material(s), if any, migrating from the first thermally-conductive composite along the first surface. The second thermally-conductive composite is also positioned relative to (e.g., on, in contact with, within a perimeter defined by, etc.) a second surface along and/or of the board level shield and the heat removal/dissipation structure, which second surface has been configured (e.g., painted, coated, sandblasted, etc.) to have a surface roughness (e.g., as shown in any one or more of FIGS. 1-10, etc.) for reducing the spreading of material(s), if any, migrating from the second thermally-conductive composite along the second surface. The surface roughness of the first and second surface may be characterized as having one or more of: an arithmetical mean height (Sa) no greater than about 1.25 (μm) (e.g., an arithmetical mean height (Sa) from about 0.01 micrometers (μm) to about 1.25 (μm), etc.); a root mean square height (Sq) no greater than about 1.5 micrometers (e.g., root mean square height (Sq) from about 0.01 micrometers to about 1.5 micrometers, etc.), and a developed interfacial area ratio (Sdr) no greater than about 250%. (e.g., a developed interfacial area ratio (Sdr) from about 0.1% to about 250%, etc.). The first and/or second thermally-conductive composites may be configured to be EMI absorbing and/or electrically conductive, such that the first and/or second composites are also operable for mitigating and/or managing EMI within the electronic device.

In an exemplary embodiment, an electronic device includes an integrated circuit, a board level shield, a heat sink, and first and second thermally-conductive composites (e.g., thermal grease, thermal putty, other thermal interface material, etc.). The first thermally-conductive composite is positioned relative to the integrated circuit and the board level shield for establishing at least a portion of a first thermally-conductive heat path between the integrated circuit and the board level shield. The second thermally-conductive composite is positioned relative to the board level shield and the heat sink for establishing at least a portion of a second thermally-conductive heat path between the board level shield and the heat sink. The first thermally-conductive composite is also positioned relative to (e.g., on, in contact with, within a perimeter defined by, etc.) a first surface along and/or of the integrated circuit and/or board level shield, which first surface has been configured (e.g., painted, coated, sandblasted, etc.) to have a surface roughness (e.g., as shown in any one or more of FIGS. 1-10, etc.) for reducing the spreading of material(s), if any, migrating from the first thermally-conductive composite along the first surface. The second thermally-conductive composite is also positioned relative to (e.g., on, in contact with, within a perimeter defined by, etc.) a second surface along and/or of the board level shield and the heat sink, which second surface has been configured (e.g., painted, coated, sandblasted, etc.) to have a surface roughness (e.g., as shown in any one or more of FIGS. 1-10, etc.) for reducing the spreading of material(s), if any, migrating from the second thermally-conductive composite along the second surface. The surface roughness of the first and second surface may be characterized as having one or more of: an arithmetical mean height (Sa) no greater than about 1.25 (μm) (e.g., an arithmetical mean height (Sa) from about 0.01 micrometers (μm) to about 1.25 (μm), etc.); a root mean square height (Sq) no greater than about 1.5 micrometers (e.g., root mean square height (Sq) from about 0.01 micrometers to about 1.5 micrometers, etc.), and a developed interfacial area ratio (Sdr) no greater than about 250%. (e.g., a developed interfacial area ratio (Sdr) from about 0.1% to about 250%, etc.). The first and/or second thermally-conductive composites may be configured to be EMI absorbing and/or electrically conductive, such that the first and/or second composites are also operable for mitigating and/or managing EMI within the electronic device.

In exemplary embodiments, the composite is a thermal interface material (TIM), such as a thermally-conductive pad, thermally-conductive gap filler, dispensable material, thermal grease, bulk putty, phase change TIM, etc. In exemplary embodiments, the composite is a thermal management and/or EMI mitigation material having a relatively high thermal conductivity (e.g., 1 W/mK (watts per meter per Kelvin), 1.1 W/mK, 1.2 W/mK, 2.8 W/mK, 3 W/mK, 3.1 W/mK, 3.8 W/mK, 4 W/mK, 4.7 W/mK, 5 W/mK, 5.4 W/mK, 6 W/mK, 8 W/mK, greater than 8 W/mK, etc.) depending on the particular materials used to make the thermal management and/or EMI mitigation material and loading percentage of the thermally conductive filler, if any. These thermal conductivities are only examples as other embodiments may include a thermal management and/or EMI mitigation material with a thermal conductivity higher than 8 W/mK, less than 1 W/mK (e.g., at least about 0.3 W/mK, etc.), or a value within a range from 1 W/mK to 8 W/mK.

Example embodiments disclosed herein may be used for a wide range of heat sources, electronic devices, and/or heat removal/dissipation structures or components (e.g., a heat spreader, a heat sink, a heat pipe, a vapor chamber, a device exterior case, housing, or chassis, etc.). For example, a heat source may comprise one or more heat generating components or devices, such as a high-power integrated circuit (IC), optical transceiver, 5G infrastructure devices (e.g., base stations, small cells, smart poles, etc.), solid-state drive (SSD), memory in video cards, set top boxes, televisions, gaming systems, automotive electronics used for autonomous driving (ADAS) (e.g., radars, multi domain controllers, cameras, etc.), a CPU, die within underfill, semiconductor device, flip chip device, graphics processing unit (GPU), digital signal processor (DSP), multiprocessor system, integrated circuit (IC), multi-core processor, etc.). Generally, a heat source may comprise any component or device that has a higher temperature than the thermal management and/or EMI mitigation material or otherwise provides or transfers heat to the thermal management and/or EMI mitigation material regardless of whether the heat is generated by the heat source or merely transferred through or via the heat source. Accordingly, aspects of the present disclosure should not be limited to use with any single type of heat source, electronic device, heat removal/dissipation structure, etc.

Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. In addition, advantages and improvements that may be achieved with one or more exemplary embodiments of the present disclosure are provided for purpose of illustration only and do not limit the scope of the present disclosure, as exemplary embodiments disclosed herein may provide all or none of the above mentioned advantages and improvements and still fall within the scope of the present disclosure.

Specific dimensions, specific materials, and/or specific shapes disclosed herein are example in nature and do not limit the scope of the present disclosure. The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and 3-9.

The terminology used herein is for the purpose of describing particular example embodiments only and is not intended to be limiting. For example, when permissive phrases, such as “may comprise”, “may include”, and the like, are used herein, at least one embodiment comprises or includes the feature(s). As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The term “about” when applied to values indicates that the calculation or the measurement allows some slight imprecision in the value (with some approach to exactness in the value; approximately or reasonably close to the value; nearly). If, for some reason, the imprecision provided by “about” is not otherwise understood in the art with this ordinary meaning, then “about” as used herein indicates at least variations that may arise from ordinary methods of measuring or using such parameters. For example, the terms “generally”, “about”, and “substantially” may be used herein to mean within manufacturing tolerances. Or for example, the term “about” as used herein when modifying a quantity of an ingredient or reactant of the invention or employed refers to variation in the numerical quantity that can happen through typical measuring and handling procedures used, for example, when making concentrates or solutions in the real world through inadvertent error in these procedures; through differences in the manufacture, source, or purity of the ingredients employed to make the compositions or carry out the methods; and the like. The term “about” also encompasses amounts that differ due to different equilibrium conditions for a composition resulting from a particular initial mixture. Whether or not modified by the term “about”, equivalents to the quantities are included.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements, intended or stated uses, or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method relating to reducing spreading of material(s), if any, migrating from a composite without having to change a formulation of the composite, the method comprising:
positioning the composite relative to a surface having a surface roughness configured for reducing the spreading of material(s), if any, migrating from the composite along the surface; and/or
configuring a surface to have a surface roughness for reducing the spreading of material(s), if any, migrating from the composite along the surface.

2. The method of claim 1, wherein the surface roughness is characterized by at least one or both of:
an arithmetical mean height (Sa) no greater than about 1.25 micrometers; and
a root mean square height (Sq) no greater than about 1.5 micrometers.

3. The method of claim 1, wherein the surface roughness is characterized by a developed interfacial area ratio (Sdr) no greater than about 250%.

4. The method of claim 1, wherein:
the surface roughness is characterized by at least one or both of an arithmetical mean height (Sa) from about 0.01 micrometers (μm) to about 1.25 (μm) and a root mean square height (Sq) from about 0.01 micrometers to about 1.5 micrometers; and
the surface roughness is further characterized by a developed interfacial area ratio (Sdr) from about 0.1% to about 250%.

5. The method of claim 1, wherein the method includes:
configuring the surface to have the surface roughness for reducing the spreading of material(s), if any, migrating from a composite along the surface; and
after the configuring, positioning the composite relative to the surface having the surface roughness to thereby reduce the spreading of material(s), if any, migrating from the composite along the surface without changing the formulation of the composite.

6. The method of claim 1, wherein the method includes:
smoothing and/or glossifying the surface to have the surface roughness for reducing the spreading of material(s), if any, migrating from a composite along the surface; and
positioning the composite on and/or adjacent the surface that has been smoothed and/or glossified to thereby reduce the spreading of material(s), if any, migrating from the composite along the surface without changing the formulation of the composite.

7. The method of claim 1, wherein:
the composite is useful for the management of heat and/or electromagnetic interference (EMI); and
the method includes reducing the spreading of material(s), if any, migrating from the composite along the surface without changing the formulation of the composite that is useful for the management of heat and/or electromagnetic interference (EMI).

8. The method of claim 1, wherein:
the method includes decreasing a surface roughness of an underlying component to at least one or both of an arithmetical mean height (Sa) no greater than about 1.25 micrometers and root mean square height (Sq) no greater than about 1.5 micrometers; and/or
the surface is configured to have a minimum thickness sufficient to decrease a surface roughness of an underlying component to at least one or both of an arithmetical mean height (Sa) no greater than about 1.25 micrometers and a root mean square height (Sq) no greater than about 1.5 micrometers.

9. The method of claim 1, wherein the method includes configuring the surface to have a surface roughness for reducing the spreading of material(s), if any, migrating from a composite along the surface by one or more of:
glossifying the surface;
transforming the surface to have a glossy, mirrored, shiny, and/or polished appearance;
polishing the surface;
painting the surface;
coating the surface;
sandblasting the surface;
plasma etching the surface;
plating the surface; and/or
transforming the surface to have the surface roughness characterized by at least one or both of an arithmetical mean height (Sa) no greater than about 1.25 micrometers and a root mean square height (Sq) no greater than about 1.5 micrometers.

10. The method of claim 1, wherein the method includes:
positioning the composite directly on the surface such that the surface is directly underneath and in contact with the composite; or
positioning the composite relative to the surface such that the surface is disposed generally around the composite; or
positioning the composite within a perimeter defined by the surface such that the composite is disposed entirely within and/or surrounded by the surface; or
positioning the composite along a second surface opposite the surface, whereby the surface is operable for reducing the spreading along the second surface of any material(s) migrating from the composite along the surface.

11. The method of claim 1, wherein:
the surface has a minimum width of at least about 5 micrometers; and/or
the surface is operable for reducing the spreading of material(s), if any, migrating from the composite along the surface such that the composite is usable substantially or entirely without material migration along the surface beyond confines of the composite.

12. The method of claim 1, wherein the surface is operable for reducing the spreading of silicone oil bleed from the composite along the surface, whereby the composite may be usable substantially or entirely without silicone migration beyond confines of the composite.

13. The method of claim 1, wherein the surface is operable for reducing the spreading of non-silicone oil bleed and/or hydrocarbon oil bleed from the composite along the surface, whereby the composite may be usable substantially or entirely without non-silicone oil bleed and/or hydrocarbon oil bleed migration beyond confines of the composite.

14. The method of claim 1, wherein the method includes dispensing the composite on the surface, adjacent to the surface, and/or on a second surface opposite to the surface after configuring the surface to have a surface roughness characterized by at least one or both of:
an arithmetical mean height (Sa) no greater than about 1.25 micrometers; and
a root mean square height (Sq) no greater than about 1.5 micrometers.

15. The method of claim 1, wherein the method includes:
configuring a component of an electronic device to have the surface with the surface roughness for reducing the spreading of material(s), if any, migrating from the composite along the surface of the component of the electronic device; and/or
positioning the composite on the surface, adjacent to the surface, and/or on a second surface opposite to the surface of the component of the electronic device that has been configured to have the surface roughness for reducing the spreading of material(s), if any, migrating from the composite along the surface of the component of the electronic device.

16. The method of claim 1, wherein:
a heat sink or other component includes a bottom surface having the surface roughness for reducing the spreading of material(s), if any, migrating from the composite along the bottom surface of the heat sink or other component, and the method includes positioning the composite on a top surface of the heat sink or other component such that the bottom surface is operable for reducing the spreading along the bottom surface of any material(s) migrating from the composite along the top surface to the bottom surface; or
a heat sink or other component includes a top surface having the surface roughness for reducing the spreading of material(s), if any, migrating from the composite along the top surface of the heat sink or other component, and the method includes positioning the composite on a bottom surface of the heat sink or other component such that the top surface is operable for reducing the spreading along the top surface of any material(s) migrating from the composite along the bottom surface to the top surface.

17. The method of claim 1, wherein the method includes smoothing and/or glossifying surface(s) at location(s) at which typical bleed may occur such that the smoothed and/or glossified surface(s) at those location(s) have the surface roughness for reducing the spreading of material(s), if any, migrating from the composite along the smoothed and/or glossified surface(s).

18. The method of claim 1, wherein the method includes smoothing, glossifying, and/or configuring a surface of a substrate having a hole that extends between top and bottom surfaces of a substrate, such that the smoothed, glossified, and/or configured surface is operable for reducing the spreading of material(s), if any, migrating from the composite through the hole, and wherein:
the smoothed, glossified, and/or configured surface defines a perimeter around the hole along the top or bottom surface of the substrate; and/or
the smoothed, glossified, and/or configured surface along and/or defines one or more vertical interior walls of the hole.

19. The method of claim 1, wherein:
the composite comprises one or more of thermally-conductive filler(s), electrically-conductive filler(s), electromagnetic wave absorbing filler(s), dielectric absorbing filler(s), and filler(s) that has two or more properties of being thermally conductive, electrically conductive, dielectric absorbing, and electromagnetic wave absorbing; and/or
the composite is a thermal phase change material, a thermal putty, a thermal grease, a dispensable thermal interface material, and/or a thermal gap filler pad; and/or
the composite is a silicone-based thermal grease or a single part ceramic filled silicone dispensable material; and/or
the composite is a thermal interface material, an EMI absorber, a thermally-conductive absorber, an electrically-conductive elastomer, an electrically-conductive composite, or a combination of two or more thereof.

20. A component or assembly configured to have a surface with a surface roughness operable for reducing the spreading of material(s), if any, migrating from a composite along the surface without having to change a formulation of the composite, wherein the composite is useful for the management of heat and/or electromagnetic interference (EMI).

21. The component or assembly of claim 20, wherein the surface roughness is characterized by at least one or both of:
an arithmetical mean height (Sa) no greater than about 1.25 micrometers; and
a root mean square height (Sq) no greater than about 1.5 micrometers.

22. The component or assembly of claim 20, wherein the surface roughness is characterized by a developed interfacial area ratio (Sdr) no greater than about 250%.

23. The component or assembly of claim 20, wherein:
the surface roughness is characterized by at least one or both of an arithmetical mean height (Sa) from about 0.01 micrometers (μm) to about 1.25 (μm) and a root mean square height (Sq) from about 0.01 micrometers to about 1.5 micrometers; and
the surface roughness is further characterized by a developed interfacial area ratio (Sdr) from about 0.1% to about 250%.

24. The component or assembly of claim 20, wherein the component or assembly comprises one or more of:
a heat removal/dissipation structure including a heat sink, a heat spreader, a heat pipe, a vapor chamber, a device exterior case, a housing, or a chassis;
a heat source of an electronic device, such as an integrated circuit or other component of the electronic device;
a component of a solid-state drive; and/or
a board level shield.

25. The component or assembly claim 20, wherein the surface comprises one or more of:
a glossified surface;
a surface having a glossy, mirrored, shiny, and/or polished appearance;
a polished surface;
a painted surface;
a coated surface;
a sandblasted surface;
a plasma etched surface; and/or
a plated surface.

26. The component or assembly of claim 20, wherein:
the surface has a minimum width of at least about 5 micrometers; and/or
the surface is configured with the surface roughness operable for reducing the spreading of material(s), if any, migrating from the composite along the surface such that the composite is usable substantially or entirely without material migration along the surface beyond confines of the composite.

27. The component or assembly of claim 20, wherein the surface is configured with the surface roughness operable for reducing the spreading of silicone oil bleed from the composite along the surface, whereby the composite may be usable substantially or entirely without silicone migration beyond confines of the composite.

28. The component or assembly of claim 20, wherein the surface is configured with the surface roughness operable for reducing the spreading of non-silicone oil bleed and/or hydrocarbon oil bleed from the composite along the surface, whereby the composite may be usable substantially or entirely without non-silicone oil bleed and/or hydrocarbon oil bleed migration beyond confines of the composite.

29. The component or assembly of claim 20, wherein the component or assembly includes a bottom surface and a top surface opposite the bottom surface, and wherein:
the bottom surface is configured to have the surface roughness operable for reducing the spreading along the bottom surface of any material(s) migrating from a composite along the top surface to the bottom surface; or
the top surface is configured to have the surface roughness operable for reducing the spreading along the top surface of any material(s) migrating from a composite along the bottom surface to the top surface.

30. The component or assembly of claim 20, wherein:
the component or assembly comprise a top surface, a bottom surface, and a hole extending between the top and bottom surfaces;
the surface having the surface roughness is configured to operable for reducing the spreading of material(s), if any, migrating from a composite through the hole; and
the surface having the surface roughness comprises at least one:
a surface defining a perimeter around the hole; and/or
a surface defining one or more vertical interior walls of the hole.

31. The component or assembly of claim 20, further comprising a composite useful for the management of heat and/or electromagnetic interference (EMI), the surface is operable for reducing the spreading of material(s), if any, migrating from the composite along the surface, and wherein:
the composite is directly on the surface such that the surface is directly underneath and in contact with the composite; or
the surface is disposed generally around the composite; or
the composite is within a perimeter defined by the surface such that the composite is disposed entirely within and/or surrounded by the surface; or
the composite is along a second surface opposite the surface, whereby the surface is operable for reducing the spreading along the second surface of any material(s) migrating from the composite along the surface.

32. The component or assembly of claim 20, wherein:
the composite comprises one or more of thermally-conductive filler(s), electrically-conductive filler(s), electromagnetic wave absorbing filler(s), dielectric absorbing filler(s), and filler(s) that has two or more properties of being thermally conductive, electrically conductive, dielectric absorbing, and electromagnetic wave absorbing; and/or
the composite is a thermal phase change material, a thermal putty, a thermal grease, a dispensable thermal interface material, and/or a thermal gap filler pad; and/or
the composite is a silicone-based thermal grease or a single part ceramic filled silicone dispensable material; and/or
the composite is a thermal interface material, an EMI absorber, a thermally-conductive absorber, an electrically-conductive elastomer, an electrically-conductive composite, or a combination of two or more thereof.
